(19) United States
(12) Patent Application Publication
(10) Pub. No.: US 2008/0080158 A1
(43) Pub. Date: Apr. 3, 2008

(54) EMI protection housing and connector seal for circuit packs installed in electronics systems

(76) Inventors: Michael A. Crocker, Long Valley, NJ (US); Bassel H. Daoud, Parsippany, NJ (US); Loren J. Holihan, Randolph, NJ (US); Thomas Joseph Schwork, Sparta, NJ (US); Christopher K. Wiese, Long Valley, NJ (US)

Correspondence Address: Lucent Technologies Inc.;Docket Administrator - Room 3J-219, 101 Crawfords Corner Road, Holmdel, NJ, 07733-3030, US

(21) Appl. No.: 11/541,034

(22) Filed: Sep. 28, 2006

(51) Int. Cl. H05K 9/00; H05K 7/18; H05K 7/14

(52) U.S. Cl. 361/818; 361/799

(57) ABSTRACT

A circuit pack housing for providing EMI protection for a circuit pack which may be inserted into an electronics system such as a telecommunications base station cabinet. The circuit pack housing has a single piece plastic design which surrounds the enclosed circuit pack. The internal walls of the circuit pack housing are metalized, and the inner surface of the housing comprises one or more grounding tabs with metalized surfaces. The metalized plastic circuit pack housing also comprises two opposite living hinges and a self latching mechanism, such that when the circuit pack is placed inside the housing and the housing is closed on itself (i.e., with use of the living hinges), the circuit pack is sealed within the housing and protected from EMI thereby. Moreover, the housing may include protruding flexible tabs at the ends thereof, which advantageously seals around the connector which energizes the circuit pack.

### FIELD OF THE INVENTION

The present invention relates generally to the field of electronics system enclosures such as, for example, telecommunications base station cabinets, and more particularly to a housing for circuit packs installed in such systems.

### BACKGROUND OF THE INVENTION

Existing designs for electronics systems such as telecommunications base station cabinets are typically quite bulky because, inter alia, it is necessary that sufficient space exists between the various circuit packs installed therein. In particular, and as is well known to those of ordinary skill in the art, such spacing is needed to provide for EMI (Electromagnetic Interference) protection between nearby circuit packs. This necessarily results in either a limitation on the number of circuit packs that can be installed in a given electronics system and/or an undesirable increase in the size and bulkiness of the system. One alternative approach to the design of electronics systems such as telecommunications base station cabinets which address this problem is to use metal housings around the individual circuit packs in order to provide the necessary EMI protection. However, such metal housings are both expensive and heavy, resulting in not only a significant additional cost, but also often requiring more than one person to install and maintain such systems. It would, therefore, be highly advantageous to provide for electronics systems such as telecommunications base station cabinets which are able to have the circuit packs contained therein stacked more closely together than in prior art designs, but without the need for expensive and heavy metal housings to provide EMI protection.

### SUMMARY OF THE INVENTION

The present invention provides a novel housing for circuit packs which may, for example, be inserted into an electronics system such as, for example, a telecommunications base station cabinet. In accordance with an illustrative embodiment of the present invention, a circuit pack housing having a single piece plastic design surrounds a circuit pack and advantageously provides EMI protection thereof. In particular, all of the internal walls of this illustrative circuit pack housing are advantageously metalized, and the inner surface of the housing advantageously comprises one or more grounding tabs with metalized surfaces, thereby grounding the circuit pack.

In accordance with one illustrative embodiment of the present invention, the metalized plastic circuit pack housing also advantageously comprises two opposing living hinges and a self latching mechanism, such that when the circuit pack is placed inside the housing and the housing is closed on itself (i.e., with use of the living hinges), the circuit pack is advantageously sealed within the housing and protected from EMI thereby. Moreover, in addition with an illustrative embodiment of the present invention, the housing may advantageously include protruding flexible tabs at the ends thereof, which advantageously seals around the connector which energizes the circuit pack. This sealing feature advantageously prevents corrosion from taking place.

Note that, in accordance with certain illustrative embodiments of the present invention, no fasteners are employed, thereby advantageously minimizing the cost of the circuit pack housing as well as the installation time thereof. Moreover, the additional EMI protection provided in accordance with the above-described illustrative embodiments of the present invention advantageously enables one to stack circuit packs more closely together and hence minimize the size of the telecommunications base station cabinet or other electronics system in which the circuit packs are installed.

### BRIEF DESCRIPTION OF THE DRAWINGS

FIG. 1 shows a front view of a prior art telecommunications base station electronics system having circuit packs installed therein.

FIG. 2 shows a front view of a telecommunications base station electronics system having circuit packs enclosed within circuit pack housings for EMI protection installed therein in accordance with an illustrative embodiment of the present invention.

FIG. 3 shows a top view of a circuit pack enclosed within a circuit pack housing for EMI protection in accordance with an illustrative embodiment of the present invention.

FIG. 4 shows a side view of a circuit pack enclosed within a circuit pack housing for EMI protection in accordance with an illustrative embodiment of the present invention.

FIG. 5 shows a top view of a circuit pack partially enclosed within a circuit pack housing for EMI protection in accordance with an illustrative embodiment of the present invention, wherein one side of the circuit pack housing is opened.

### DETAILED DESCRIPTION OF THE PREFERRED EMBODIMENTS

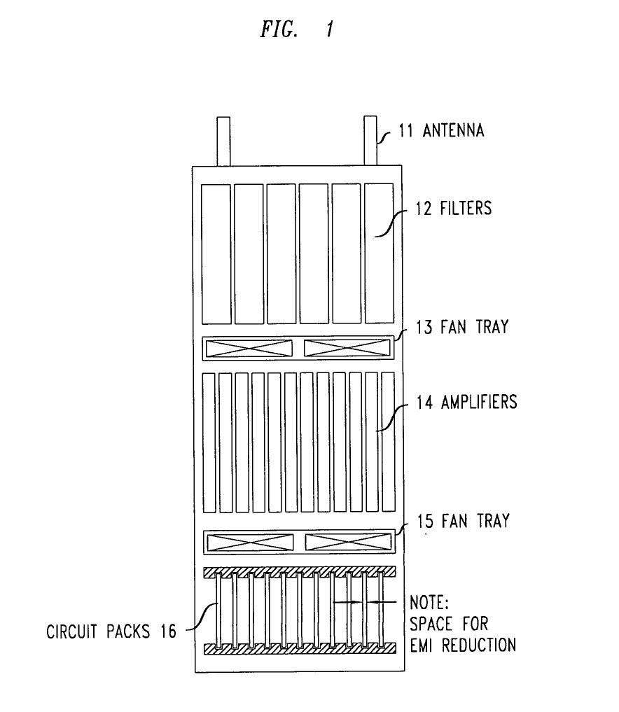

FIG. 1 shows a front view of a prior art telecommunications base station electronics system. The prior art system of FIG. 1 includes a number of component sections (i.e., shelves), and comprises antennae 11 (two are shown), a shelf comprising filters 12, a shelf comprising amplifiers 14, and a shelf comprising circuit packs 16, as well as fan tray 13 (positioned between the shelf comprising filters 12 and the shelf comprising amplifiers 14), and fan tray 15 (positioned between the shelf comprising amplifiers 14 and the shelf comprising circuit packs 16).

As can be seen in the figure, circuit packs 16 may be installed in their corresponding shelf with use of slotted openings in the top and bottom portions of the shelf, thus allowing the circuit packs to be slid into place. Also, as is typical, the back sides of many of the included components may be connected to either a cabling harness or, preferably, a PWB (Printed Wiring Board) backplane (which is not visible in the figure). Note that in order to provide EMI protection for each of circuit packs 16, a significant amount of space is required between each adjacent pair of circuit packs 16, thereby limiting the number of such circuit packs which may be included in the shelf and/or increasing the bulkiness of the resultant system.

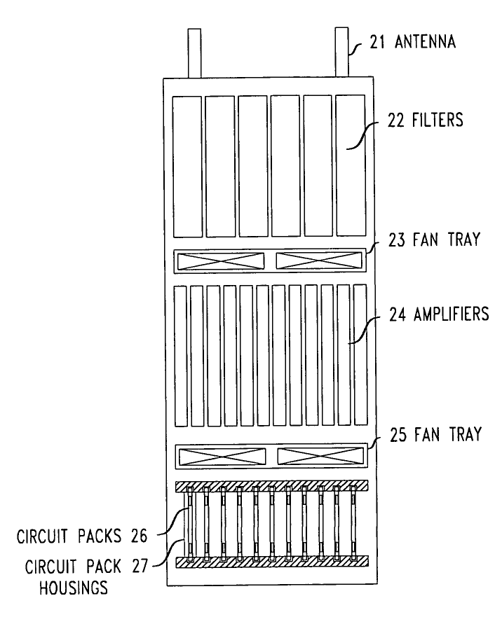

FIG. 2 shows a front view of a telecommunications base station electronics system having circuit packs enclosed within circuit pack housings for EMI protection installed therein in accordance with an illustrative embodiment of the present invention. The illustrative telecommunications base station electronics system of FIG. 2 includes a number of component sections (i.e., shelves), and comprises antennae 21 (two are shown), a shelf comprising filters 22, a shelf comprising amplifiers 24, and a shelf comprising circuit packs 26, as well as fan tray 23 (positioned between the shelf comprising filters 22 and the shelf comprising amplifiers 24), and fan tray 25 (positioned between the shelf comprising amplifiers 24 and the shelf comprising circuit packs 26).

Although not visible, it may be assumed that the back sides of many of these components are advantageously connected to a PWB (Printed Wiring Board) backplane. Moreover, in order to provide EMI protection in accordance with the principles of the present invention, each of circuit packs 26 is advantageously enclosed in a corresponding circuit pack housing 27, which is constructed in accordance with an illustrative embodiment of the present invention. Also, as can be seen in the figure, circuit packs 26, together with their corresponding circuit pack housings 27, are advantageously installed in their corresponding shelf with use of slotted openings in the top and bottom portions of the shelf, thus allowing the circuit packs (together with their corresponding circuit pack housings) to be slid into place.

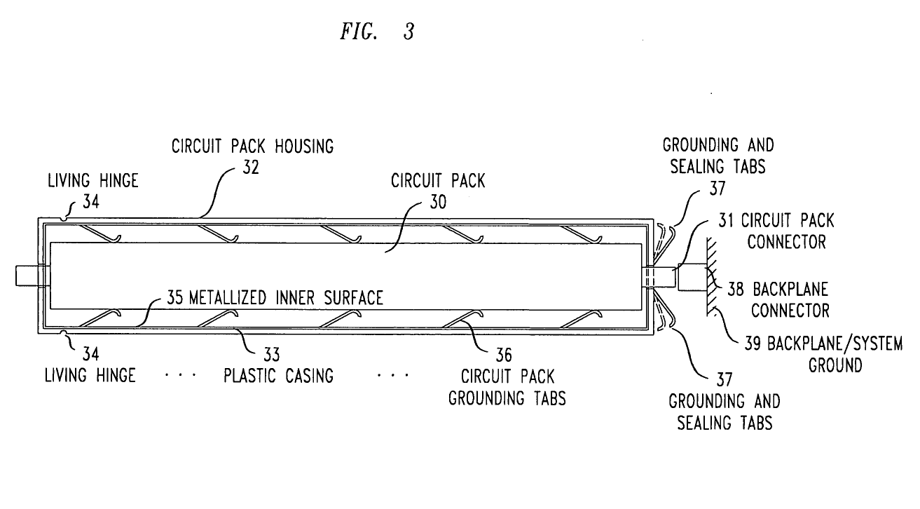

FIG. 3 shows a top view of a circuit pack enclosed within a circuit pack housing for EMI protection in accordance with an illustrative embodiment of the present invention. As shown in the figure, circuit pack 30, which includes circuit pack connector 31, is fully enclosed within illustrative circuit pack housing 32. Note that circuit pack connector 31 is advantageously provided to connect circuit pack 30 to the system backplane in order to energize the circuit pack. (Also shown in the figure is corresponding backplane connector 38 into which circuit pack connector 31 is to be inserted, as well as backplane/system ground 39.)

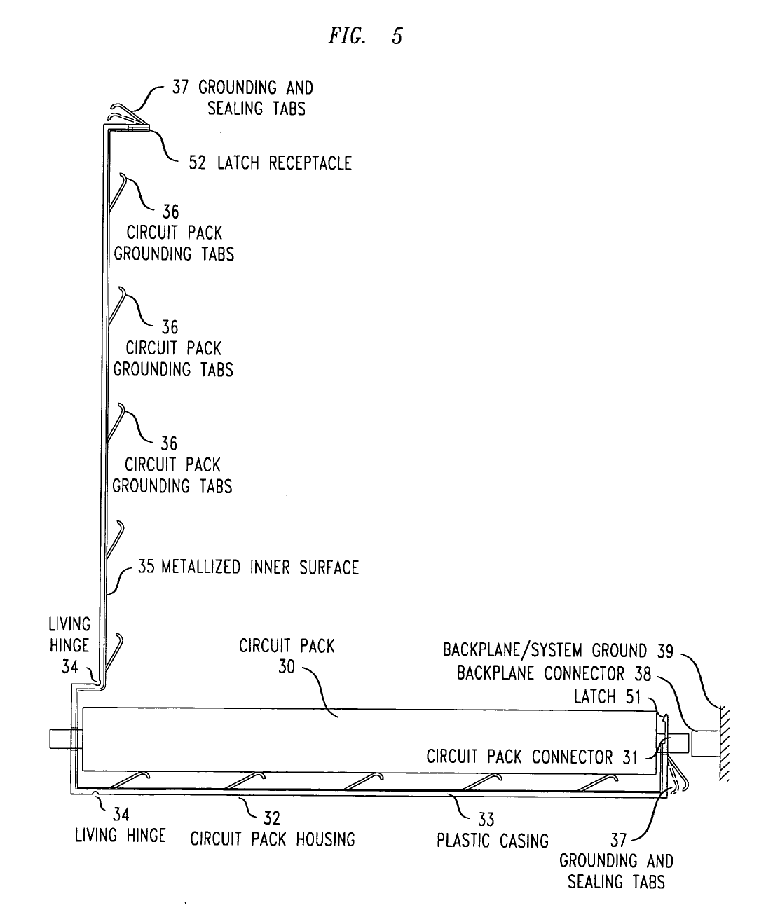

Circuit pack housing 32 comprises plastic casing 33, which advantageously includes two “living” hinges 34 molded therein. (See description of FIG. 5 below for a detailed discussion of “living” hinges 34.) Circuit pack housing 32 also advantageously comprises metalized inner surface 35, which advantageously has a plurality of metalized circuit pack grounding tabs 36 physically attached and electrically connected thereto. Each of metalized circuit pack grounding tabs 36 are advantageously positioned such that they provide grounding of circuit pack 30 at a corresponding plurality of locations. That is, grounding tabs 36 are advantageously located so that, when circuit pack housing 32 is closed around circuit pack 30, grounding tabs 36 make physical and electrical contact with grounding paths provided on the surface of circuit pack 30.

In accordance with the illustrative embodiment of the present invention shown in FIG. 3, circuit pack housing 32 also comprises a plurality (two are shown) of protruding grounding and sealing tabs 37 which are advantageously flexible so that they can be operated in order to affix circuit pack connector 31 into backplane connector 39. Moreover, grounding and sealing tabs 37 are advantageously metalized and electrically connected to metalized inner surface 35, in order to advantageously connect and seal the circuit pack ground to backplane/system ground 39 when operated to affix circuit pack connector 31 into backplane connector 39. Such a sealing feature advantageously prevents corrosion from taking place.

In accordance with one illustrative embodiment of the present invention, the plastic casing of the circuit pack housing may, for example, comprise a nylon-based plastic such as, for example, grilamid®. (Grilamid® is a nylon-based polyamide 12 injection moulding and extrusion material product from, and a registered trademark of, EMS-Chemie (Asia) Ltd, and is fully familiar to those skilled in the art.) Also, in accordance with one illustrative embodiment of the present invention, the area surrounding circuit pack connecter 31 may be advantageously filled with silicone gel in order to provide improved sealing between circuit pack connector 31 and backplane connector 39.

Additionally, in accordance with one illustrative embodiment of the present invention, metalized circuit pack grounding tabs 36 may comprise tabs made of metalized plastic. That is, as is well known to those skilled in the art, metal may be sprayed onto a plastic material so that the material advantageously becomes electrically conducting, and yet still retains many of the advantages of a plastic material (such as, for example, its light weight).

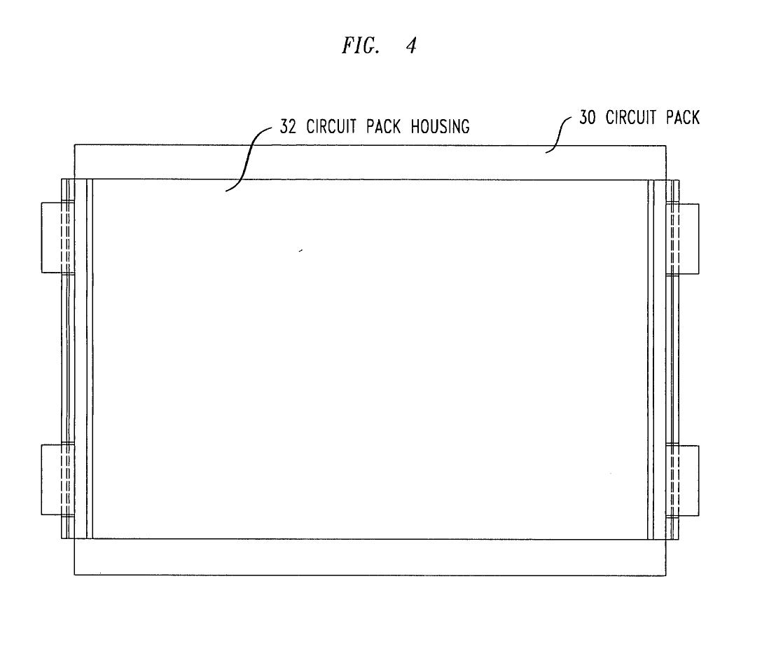

FIG. 4 shows a side view of a circuit pack enclosed within a circuit pack housing for EMI protection in accordance with an illustrative embodiment of the present invention. In particular, the figure shows circuit pack 30 enclosed within circuit pack housing 32.

FIG. 5 shows a top view of a circuit pack partially enclosed within a circuit pack housing for EMI protection in accordance with an illustrative embodiment of the present invention, wherein one side of the circuit pack housing is opened. In particular, as shown in the figure, circuit pack 30 is partially enclosed within illustrative circuit pack housing 32, which has one of its two sides in an opened position with respect to circuit pack 30.

As can be clearly seen in FIG. 5, illustrative circuit pack housing 32 comprises plastic casing 33 which advantageously includes two “living” hinges 34 molded therein. Specifically, these “living” hinges may, for example, comprise a curved notch molded directly into the plastic of plastic casing 33, thereby advantageously allowing that portion of the plastic casing itself to be operable as a hinge. The use of such “living’ hinges, fully familiar to those of ordinary skill in the art, advantageously minimizes the cost of the circuit pack housing as well as the associated assembly and installation time.

In accordance with other illustrative embodiments of the present invention, separate physical hinges (i.e., mechanical devices which are attached to plastic casing 33) may alternatively be used. In addition, although the illustrative embodiment of the present invention as shown herein comprises two “living” hinges, in accordance with other illustrative embodiments of the present invention, a different number of hinges—whether “living” hinges or separate physical hinges—may be used. For example, it will be obvious to those of ordinary skill in the art that a circuit pack housing with just a single operable hinge may be devised in accordance with the principles of the present invention.

In accordance with one illustrative embodiment of the present invention, the illustrative circuit pack housing shown in FIG. 5 also advantageously comprises latch 51 and corresponding latch receptacle 52, which together operate to enable circuit pack housing 32 to completely enclose circuit pack 30 when closed (i.e., when latch 51 is inserted into latch receptacle 52). Thus, when closed, circuit pack housing 32 serves to seal circuit packet 30, and, in accordance with the principles of the present invention, thereby serves to protect the circuit pack from EMI (e.g., as a result of grounded metalized inner surface 35, which fully surrounds circuit pack 30 when circuit pack housing 32 is fully closed). Advantageously, the latching mechanism (i.e., latch 51 and latch receptacle 52) may, like the “living” hinges described above, be molded directly into the plastic of plastic casing 33. This also advantageously minimizes the cost of the circuit pack housing as well as the associated assembly and installation time. However; in accordance with other illustrative embodiments of the present invention, separate physical latching mechanisms (i.e., mechanical devices which are attached to plastic casing 33) may alternatively be used.

### Addendum to the Detailed Description

It should be noted that all of the preceding discussion merely illustrates the general principles of the invention. It will be appreciated that those skilled in the art will be able to devise various other arrangements, which, although not explicitly described or shown herein, embody the principles of the invention, and are included within its spirit and scope. In addition, all examples and conditional language recited herein are principally intended expressly to be only for pedagogical purposes to aid the reader in understanding the principles of the invention and the concepts contributed by the inventor to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. It is also intended that such equivalents include both currently known equivalents as well as equivalents developed in the future—i.e., any elements developed that perform the same function, regardless of structure.

What is claimed is:

1. A circuit pack housing for providing EMI protection for a circuit pack contained therein when said circuit pack housing containing said circuit pack is installed in an electronics system, the circuit pack housing comprising:
a plastic casing adapted to surround the circuit pack when the circuit pack is contained in the circuit pack housing, the plastic casing having a plurality of internal walls thereof and having a metalized inner surface on one or more of said internal walls thereof; and
one or more grounding tabs, each of said grounding tabs having a metalized surface and attached at one end thereof to said metalized inner surface of one of said internal walls of said plastic casing, wherein each of said grounding tabs is adapted to provide electrical grounding for the circuit pack when the circuit pack is contained in the circuit pack housing.

2. The circuit pack housing of claim 1 wherein said plastic casing has a metalized inner surface on all of said plurality of internal walls of said plastic casing.

3. The circuit pack housing of claim 1 wherein said circuit pack housing has a single piece design.

4. The circuit pack housing of claim 1 wherein the plastic casing comprises one or more living hinges operable to open and close said circuit pack housing.

5. The circuit pack housing of claim 4 wherein each of said living hinges is effectuated by the presence of a curved notch having been molded directly into said plastic casing.

6. The circuit pack housing of claim 4 wherein the plastic casing comprises exactly two living hinges.

7. The circuit pack housing of claim 1 wherein the plastic casing comprises a latching mechanism, said latching mechanism comprising a latch and a latch receptacle each effectuated by having been molded directly into said plastic casing.

8. The circuit pack housing of claim 1 wherein the circuit pack comprises a circuit pack connector for connecting said circuit pack to a backplane of said electronics system, and wherein the circuit pack housing further comprises one or more protruding flexible tabs adapted to be operable to attach the circuit pack connector comprised in the circuit pack to said backplane of said electronics system.

9. The circuit pack housing of claim 8, wherein said backplane of said electronics system comprises a backplane ground, and wherein each of said one or more protruding flexible tabs
(i) has a metalized surface which is electrically connected to said metalized inner surface of said one or more of said internal walls of said plastic casing, and
(ii) is adapted to provide electrical grounding to said circuit pack when operated to attach the circuit pack connector comprised in the circuit pack to said backplane of said electronics system by electrically connecting said metalized inner surface of said one or more of said internal walls of said plastic casing to said backplane ground.

10. The circuit pack housing of claim 8 further comprising silicone gel for providing an improved seal when said one or more protruding flexible tabs are operated to attach the circuit pack connector comprised in the circuit pack to said backplane of said electronics system.

11. The circuit pack housing of claim 1 wherein said plastic casing comprises a nylon-based plastic.

12. The circuit pack housing of claim 11 wherein said nylon-based plastic comprises grilamid®.

13. The circuit pack housing of claim 1 wherein each of said one or more grounding tabs are made of metalized plastic.

14. An electronics system comprising a plurality of circuit packs, each of said circuit packs being enclosed in a circuit pack housing for providing EMI protection therefor, each of said circuit pack housings for a corresponding circuit pack comprising:
a plastic casing surrounding the corresponding circuit pack, the plastic casing having a plurality of internal walls thereof and having a metalized inner surface on one or more of said internal walls thereof; and
one or more grounding tabs, each of said grounding tabs having a metalized surface and attached at one end thereof to said metalized inner surface of one of said internal walls of said plastic casing, wherein each of said grounding tabs is adapted to provide electrical grounding for the corresponding circuit pack.

15. The electronics system of claim 14 wherein said electronics system comprises a telecommunications base station.
